(19) United States
(12) Patent Application Publication
(10) Pub. No.: US 2006/0152957 A1
(43) Pub. Date: Jul. 13, 2006

(54) Circuit arrangement and method for setting operating parameters in a RAM module

(76) Inventor: Andre Schaefer, Munchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/258,838

(22) Filed: Oct. 26, 2005

(30) Foreign Application Priority Data
Oct. 26, 2004 (DE) DE 10 2004 051 95

(51) Int. Cl. G11C 5/00

(52) U.S. Cl. 365/52

(57) ABSTRACT

An inventive circuit arrangement for setting selected operating parameters in a RAM module contains, for each element in a set of M different operating parameters, a respective value register which is individually assigned, can be set using an individual control signal and is intended to store an item of value information that has been input for the relevant parameter. A first group of external terminals is dedicated to inputting destination information which indicates the respective parameter to be set, and a second group of external terminals is dedicated to inputting value information for the parameters. Provision is also made of a selection device which can be controlled using the destination information which has been input at the first group of terminals in order to transmit the value information which has been input at the second group of terminals only to that value register which is assigned to the indicated parameter. One advantageous use of the inventive circuit arrangement is a method for individually trimming operating parameters of the data transmission drivers of the RAM module.

### CROSS-REFERENCE TO RELATED APPLICATIONS

This application claims foreign priority benefits under 35 U.S.C. §119 to co-pending German patent application number DE 10 2004 051 958.7-55, filed 26 Oct. 2004. This related patent application is herein incorporated by reference in its entirety.

### BACKGROUND OF THE INVENTION

1. Field of the Invention

The invention relates to a circuit arrangement for setting selected operating parameters in a RAM module. The invention also relates to setting methods using this circuit arrangement.

2. Description of the Related Art

As is known, the acronym RAM stands for “Random Access Memory”, that is to say a read/write memory having the capability to directly access addressed memory cells in a random manner. Dynamic RAMs (DRAMs), in particular “synchronous” dynamic RAMs (SDRAMs), as are used as main memories or graphics memories in computers, are a preferred but not exclusive field of the invention.

A RAM module is usually integrated on a semiconductor chip and contains a large number of memory cells which are arranged in rows and columns in the form of a matrix and are usually distributed among a plurality of banks which can be addressed individually. The chip has a plurality of external terminals including, inter alia, address terminals for applying the information for addressing the respective memory cells which are to be addressed, data terminals for inputting and outputting the memory data which are to be written to, and read out from, the addressed memory cells, and command terminals for applying commands in order to control operation of the memory. During operation, the RAM module is connected, via the terminals mentioned, to a “controller” which transmits the memory data which are to be written, receives the data which have been read out and also transmits the address information and the control commands.

In order to make the RAM module flexible in terms of its possible uses, that is to say to be able to adapt it to various types of use and environments, means are usually provided in order to set various state variables (referred to here as “operating parameters” or “parameters” for short) as desired. These “mode” settings are usually effected by the controller during an initialization phase each time the module is started up, the controller transmitting the necessary control information to the module to this end, and the control information being stored in a mode register in said module. The contents of the mode register then determine the values of said parameters for subsequent useful operation of the module.

In order to store the control information in the mode register, the controller transmits a setting command MRS (“mode register set”) in the form of a particular pattern of parallel bits to the command terminals of the RAM module and, at the same time, the control information (likewise in the form of a pattern of parallel bits) to other existing terminals of the module. Since, during the initialization phase, memory data are not transmitted between the RAM module and the controller and memory cells are therefore not addressed either, the address terminals and also the data terminals may be used during this time to input the control information. A particular set of these terminals is thus selected in order to perform the role of control information terminals during the initialization phase. This dedicated set may be a particular part (for example only the address terminals) or all of the address and data terminals. Each control information terminal is connected to the data input of precisely one cell (which is assigned only to said terminal) in the mode register whose set input is triggered by the setting command MRS.

The size (number of cells) of the mode register is thus limited to the number of control information terminals. This restricts the setting possibilities, to be precise both as regards the number of parameters which can be set and as regards the range of variation or the fineness when setting the parameter values. This restriction leads to the fact that many mode settings which would be desirable per se have hitherto not been able to be implemented in practice. It would thus be advantageous, for example, to be able to respectively set one or more operating parameters, for example the current intensity or the duty ratio of the transmitted data pulses, in an individual and relatively fine manner for each data transmission driver (off-chip driver OCD) at the data terminals of the RAM module. The total number of bits required for this purpose for the setting information by far exceeds the number of available control information terminals even if all of the address and data terminals are dedicated to this. In order to be able to retain the previously customary organization of the mode register, it would be necessary to provide a large number of additional external control information terminals on the chip but this is undesirable for reasons of space.

### SUMMARY OF THE INVENTION

The object of the invention is to increase the number of setting options for operating parameters of a RAM module without, for this purpose, having to increase the number of external terminals which are used to input the setting information. According to the invention, this object is achieved by means of the circuit arrangement characterized in patent claim 1.

Accordingly, the invention is implemented in a circuit arrangement for setting selected operating parameters in a RAM module which has a command input for receiving external operating commands and has further terminals for inputting and outputting memory data and for inputting address information, a subset of these further terminals also being dedicated to inputting control information for various operating parameters, and provision being made of a register arrangement which can be activated using a control signal in order to store the control information which has been input at the dedicated control information terminals. According to the invention, the register arrangement contains, for each element in a set of M different operating parameters, a respective value register which is individually assigned, can be set using an individual control signal and is intended to store an item of value information that has been input for the relevant parameter. A first group of control information terminals is dedicated to inputting destination information which indicates the respective parameter to be set, and a second group of control information terminals is dedicated to inputting value information for the parameters. Provision is also made of a selection device which can be controlled using the destination information which has been input at the first group of terminals in order to transmit the value information which has been input at the second group of terminals only to that value register which is assigned to the indicated parameter.

The inventive circuit arrangement makes it possible for those terminals of the RAM module which are dedicated to inputting the control information to be repeatedly used to make a multiplicity of settings for which an amount of information which contains far more bits than corresponds to the number of dedicated terminals is needed overall. This opens up the way for settings which have hitherto not been able to be implemented for reasons of a limited number of terminals on the module.

Special embodiments of the invention and a method for using an inventive circuit arrangement are characterized in subordinate patent claims. In order to explain the invention in more detail, various exemplary embodiments are described below with reference to drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically shows a first variant of an inventive circuit arrangement;

FIG. 2 shows a second variant of an inventive circuit arrangement;

FIG. 3 shows a third variant of an inventive circuit arrangement; and

FIG. 4 shows a flowchart for a trimming method using an inventive circuit arrangement.

### DETAILED DESCRIPTION OF THE PREFERRED EMBODIMENT

In the figures, the same abbreviations in capital letters are respectively used to denote identical or similar elements, a number placed afterward respectively being used for more precise identification. In the following description, a colon “:” between two such numbers represents the word “to”. By way of example, “AP1:3” is thus to be read as “AP1 to AP3”.

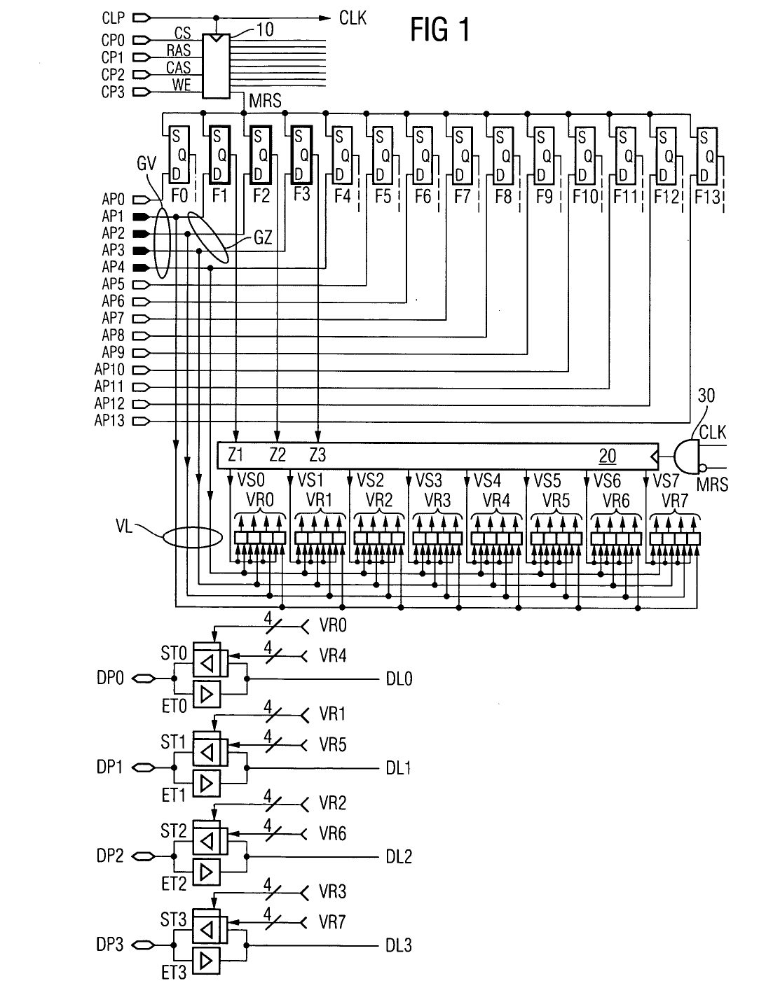

The circuit arrangement which is shown in different variants in FIGS. 1 to 3 forms part of a RAM module which is integrated on a chip. The left-hand edge of each figure shows a plurality of external terminals of the chip, which are also referred to as “pins” and are connected to corresponding terminals of a controller (not shown) during operation. Four “command pins” CP0:3, fourteen “address pins” AP0:13, four “data pins” DP0:3 and one “clock pin” CLP are shown.

The command pins CP form a command input for receiving commands in the form of a 4-bit parallel code word which is decoded in a downstream command decoder 10 in order to respectively activate one of a plurality of command lines on the basis of the bit pattern of the code word. The four command bits on the pins CP0:3 are usually denoted CS, RAS, CAS, WE for historical reasons. In each clock period of a clock signal CLK which is applied to the clock pin CLP, some selected code word, which is either an operation command that orders some operation in the RAM module or a so-called “NOP” (no operation) command, is applied to the command pins CP. The operation commands include, inter alia, the “write” command for activating the writing of data, the “read” command for activating the reading-out of data and the “mode register set” command (already mentioned), abbreviated to MRS, for activating an operation for setting operating parameters of the RAM module.

The data pins DP are used to input and output the memory data and, for this purpose, are each connected to the input of a reception driver ET and the output of a transmission driver ST. These drivers have control terminals (not shown) in order to activate the reception drivers ET in response to a “write” command so that they pass the write data bits which have been applied to the data pins DP to assigned data lines DL of an internal data bus. The transmission drivers ST are activated in response to a “read” command in order to transmit the read data bits which appear on the data lines DL to the data pins DP.

The data memory cells to which the write data are to be written or from which the read data are to be read out are selected using address bits which are applied to the address pins AP at a suitable point in time. A particular subset of address pins is used to address the banks and the other address pins are used to address the rows and columns. The row and column address bits are decoded in row and column address decoders. The address decoders and their connections to the address pins AP are not shown in FIG. 1, nor is the matrix of the memory cells and the internal control circuit for connecting the data transmission paths between the data lines DL and the respectively addressed memory cells. All of these elements may be of a conventional type, as is generally known in the field of RAM modules.

The numbers of address pins AP and data pins DP shown in FIGS. 1 to 3 are only an example. The case (shown) of 4 data pins allows data words to be written and read in a parallel format with a word length of 4 bits, that is to say each address is used to address a group of 4 memory cells in the memory matrix (so-called “×4 module”). RAM modules having 8 or 16 or even 32 data pins are also currently customary, the latter (that is to say ×32 modules) being used, in particular, as graphics memories. The requisite number of address bits AP depends, on the one hand, on the memory size (total number of data memory cells) and, on the other hand, on the number of data pins DP used. Accordingly, the number of address pins AP may also be less than or greater than in the example shown.

As already mentioned, the address pins AP and/or the data pins DP may be used to input control information for setting various operating parameters of the RAM module. In the case of the exemplary embodiments described here, it is only the address pins AP which are used as control information terminals. To this end, each of the fourteen address pins AP1:13 is connected to the data input D of a respectively assigned copy of fourteen D-type flip-flops (data flip-flops) F0:13 whose trigger or set inputs S are connected to that command line which is activated, that is to say changes to the logic value “1”, when the “mode register set” command (MRS command) is received. The flip-flops F0:13 thus form a 14-cell “mode register” that holds the control information which comprises 14 bits and is applied to the address pins A0:13 at the time of the MRS command. The Q outputs of the flip-flops thus provide a replica of this information. The arrangement corresponds to the prior art in this respect.

In the prior art, the full set of cells in the mode register F0:13 is divided into a plurality of subsets in such a manner that each subset is respectively permanently assigned to a particular operating parameter in order to store the value (which is to be set) of only this parameter. That is to say that each of these subsets forms, per se, a value register whose Q outputs are permanently connected to a control element for the permanently assigned parameter.

However, this is different in the inventive circuit arrangement. As shown in FIGS. 1 to 3, a dedicated value register VRi is respectively provided for each parameter in a set of M=8 different parameters, it being possible (in contrast to the prior art) to “selectively” set said value register using a dedicated trigger signal VSi (the letter i=0, 1, . . . 7 represents the respective number of the value register VR here). In the example shown, each of the value registers VR0:7 contains four D-type flip-flops for storing a 4-bit word which prescribes the value for the assigned parameter and is transmitted in a parallel format via a four-wire line bundle VL. This line bundle VL is connected to the data inputs of the four flip-flops in each of the eight value registers VR0:7.

One of the eight value registers VR0:7 is respectively selected in a targeted manner using a 1-of-8 decoder 20 which, for this purpose, requires an item of destination information of 3 bits which are applied to three assigned inputs Z1, Z2, Z3 of the decoder. The pattern of these 3 bits determines which of the trigger signals VS0:7 is activated and thus also determines the value register VR0:7 in which the control information (which appears on the line bundle VL) is stored.

The described system of using a respective value register VR (which can be selectively addressed) for each one of a plurality of parameters and the provision of an item of control information in the form of a combination of an item of destination information, which selects the respective value register, and an item of value information, which specifies the value (which is to be set) of the parameter, make it possible, as stated, to repeatedly use dedicated terminals to set operating parameters. In this case, there are various possible ways of assigning the dedicated terminals.

One possibility is to at least partially use the same terminals to input the destination information and to input the value information, it being necessary to input the two items of information in temporal succession for each parameter which is to be set. In this case, two variants are again possible: in a first variant, the destination information is input first and then the value information; in a second variant, the order is reversed. In both cases, the number of dedicated control information terminals only needs to be as large as the number of bits in the “longest” information word. In the example described here, the value information always comprises 4 bits and is thus “longer” than the destination information which comprises 3 bits. 4 terminals are therefore needed to input the control information.

FIG. 1 shows a circuit arrangement for the first variant. The four address pins AP1:4 are selected as the control information terminals which are to be repeatedly used, the pins AP1:4 forming a group GV to which the 4-bit value information is to be applied. The pins AP1:3 form a group GZ to which the 3-bit destination information for selecting one of the eight value registers VR0:7 is to be applied (the group GZ is a subset of the pins of the group GV).

Since, in the variant shown in FIG. 1, the 3-bit destination information is to be input first at the pins AP1:3 (group GZ), some means need to be provided in order to temporarily hold this information in the circuit arrangement, to be precise in a manner such that it is decoupled from the pins AP1:3, so that the value information which is subsequently input at the pins AP1:4 is supplied to that value register VR which is determined by the destination information. In the example shown, the three flip-flops F1:3 of the mode register are used for this purpose, the D inputs of said flip-flops being connected to the pins AP1:3 and said flip-flops being triggered by the MRS command so that they hold the destination information. This information is retained after the MRS command disappears and is passed from the Q outputs of the flip-flops F1:3 to the three inputs of the decoder 20. In each subsequent clock pulse after the MRS command has disappeared (and an NOP command, for example, is input instead), the decoder 20 is clocked in order to activate the trigger signal VSi for that value register VRi which is determined by the destination information. The decoder 20 can be clocked, for example, by the output of an AND gate 30 which combines the clock signal CLK with the inverted signal of the MRS command line (that is to say with the negation of the MRS command).

After the MRS command has disappeared, the 4-bit value information for the parameter determined by the previous destination information can be input at the pins AP1:4 (group GV). In the variant shown in FIG. 1, these pins are connected to the line bundle VL which leads to the data inputs of all eight value registers VR0:7. However, thanks to the above-described operation of the decoder 20, the value information passes, as desired, only to that value register VRi which is selected by the destination information.

The same pins A1:4 can then be used to set another parameter by repeating the above-described operation, with the MRS command being input again, with an item of destination information for selecting another one of the value registers VR0:7 and with an item of value information for this other register.

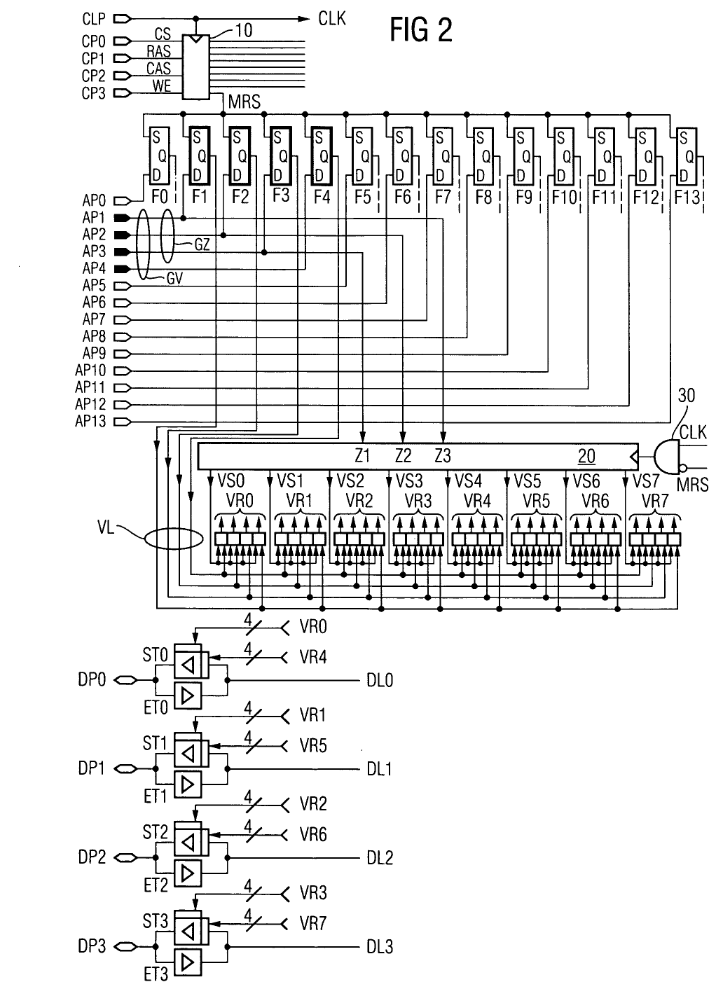

FIG. 2 shows a circuit arrangement for the second variant. The four address pins AP1:4 are also selected here as the control information terminals which are to be repeatedly used, the pins AP1:4, in this case, also forming the group GV to which the 4-bit value information is to be applied, and the pins AP1:3 forming the group GZ to which the 3-bit destination information for selecting one of the eight value registers VR0:7 is to be applied. The difference from the first variant shown in FIG. 1 is only that (a) the line bundle VL which supplies the bits of the value information to the data inputs of the value registers VR0:7 is not connected to the pins AP1:4 but instead to the Q outputs of the mode register flip-flops F1:4 whose data inputs are connected to the pins AP1:4, and that (b) the three inputs of the decoder 20 are directly connected to the pins AP1:3.

As can easily be seen, during operation of this second variant shown in FIG. 2, the value information must be input first at the group of pins GV when the MRS command appears in order to hold this information in the line bundle VL using the flip-flops F1:4. If, during one of the next clock pulses after the MRS command has disappeared, the destination information is then input at the group of pins GZ, the decoder 20 decodes this information in order to trigger the value register VRi determined by said information so that it stores the value information held in the line bundle VL.

The two variants shown in FIGS. 1 and 2 are functionally equivalent. However, the variant shown in FIG. 1 may be more advantageous if the destination information contains fewer bits than the value information, as in the example shown. In these cases, there is a set of pins which are required only for value information and not for the destination information. No flip-flop for holding the relevant information bit is required for these pins (it is only the pin AP4 in FIG. 1), with the result that the number of flip-flops in the mode register can be reduced. That is to say that the flip-flop F4 can be omitted for the case shown in FIG. 1.

In a similar manner, the variant shown in FIG. 2 could be more advantageous if the value information contains fewer bits than the destination information. In these cases, there would be a set of pins which are required only for the destination information and not for the value information. No flip-flop for holding the relevant information bit is required for these pins, with the result that the number of flip-flops in the mode register can be reduced.

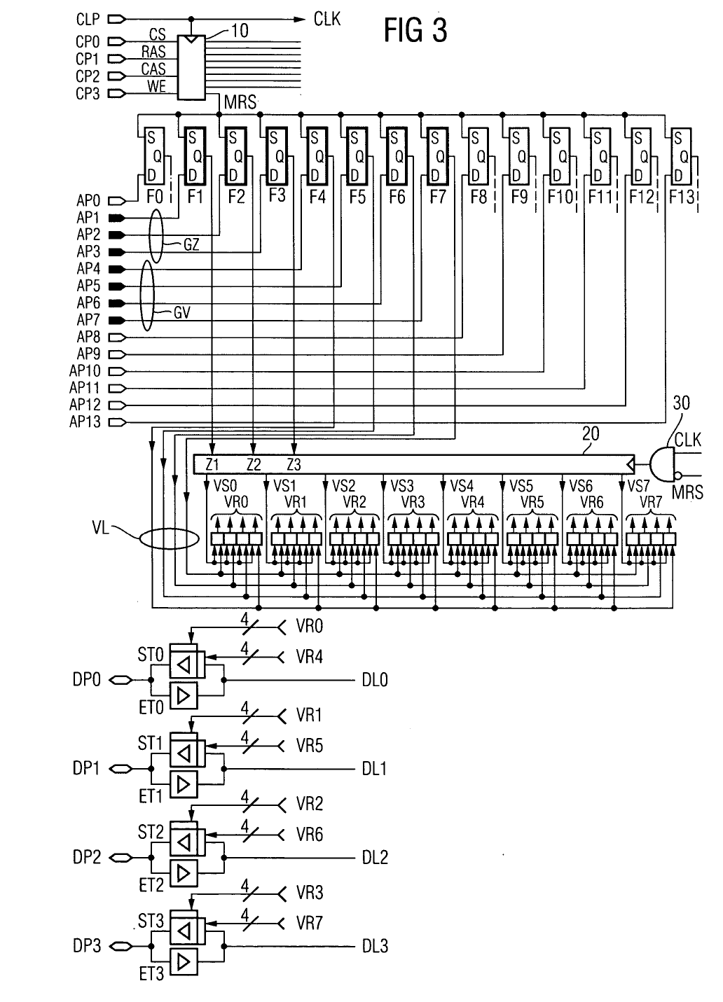

In a departure from the variants shown in FIGS. 1 and 2, it is also possible to use respectively different terminals to input the destination information and to input the value information, with the result that the two items of information can be simultaneously input for a parameter which is to be set. A corresponding third variant is shown in FIG. 3.

In the variant shown in FIG. 3, the groups GZ and GV of address pins which are to be occupied by the destination information and by the value information are disjunct subsets AP1:3 and AP4:7 of the set of address pins. The inputs of the decoder 20 are connected to the Q outputs of the D-type flip-flops F1:3 whose D inputs are connected to the pins of the group GZ. The wires of the line bundle VL which lead to the data inputs of the value registers VR0:7 are connected to the Q outputs of the D-type flip-flops F4:7 whose D inputs are connected to the pins of the group GV. If the MRS command disappears after the destination and value information has been input, the decoder 20 responds during the next clock pulse in order to trigger that value register VRi which is determined by the destination information so that it holds the value information. When the MRS command is input again, the destination and value information for another of the value registers VR0:7 can then be applied to the same groups of pins GZ and GV in order to set another parameter.

In the above-described examples, a subset of pins is reserved for repeatedly inputting control information (these “reserved” pins are depicted in solid black in the figures). The other pins can be used, in a conventional manner, to write information for other settings to the flip-flops of the mode register which are connected to these pins, with the result that these flip-flops can be used directly as value registers for other parameters, as in the prior art. The information for these flip-flops must be present at the relevant pins at least during the last MRS command.

Of course, the invention is not restricted to the examples described. Numerous modifications or alternatives to the circuit arrangements described are possible in order to implement the principle on which the invention is based. Some of these are discussed below.

The “word length” (that is to say the number of parallel bits) of the destination information and of the value information and thus the number of pins to be reserved for repeatedly inputting control information are determined by the number of parameters to be set and by the desired resolution of the value information. Depending on the requirements, a more or less large subset of pins or even the full set of pins may thus be reserved for repeated input.

The word length of the destination information may be equal to the word length of the value information or may be shorter or longer than the latter. If the two groups of pins GZ and GV for the destination information and the value information are not disjunct groups, the pins of one group are preferably a subset of the pins of the other group (or are identical to the latter if the destination information and the value information have the same word length). However, it is also possible for the two groups to overlap only partially, with the result that the intersection set of pins of the two groups does not comprise an entire group.

The invention is not restricted to reserving exclusively address pins for repeatedly inputting control information. Data pins may also be used for this purpose.

The inventive circuit arrangement may also be designed in such a manner that various disjunct subsets of pins are respectively used for repeated input for various disjunct sets of parameters, one group GZ, in each of these subsets, being used to input an item of destination information which indicates that parameter in the relevant set of parameters which is to be set, and one group GV being used to input the value information for the indicated parameter. A respective dedicated subset of holding flip-flops then needs to be reserved, and a dedicated decoder needs to be provided, for each set of parameters, said decoder selecting the value register for that parameter in precisely this set of parameters which is determined by the destination information. This variant allows one parameter from a plurality of different sets of parameters to be respectively set at the same time.

The invention makes it possible to set an unlimited multiplicity of different parameters of a RAM module using a limited number of external terminals. As stated, this opens up a multiplicity of new setting possibilities, for example also the individual setting of operating parameters for each individual transmission driver on the data lines of the module. One advantageous use of the invention relates to these settings and is explained in more detail below.

In RAM modules, in particular in modules which are operated at very high speed, for example graphics memories, it may be desirable to be able to individually trim (“train”) many parameters of the data transmission drivers, to be precise within the working environment of the module. The parameters which are to be trimmed may be, inter alia:
intensity of the driver current. This parameter can be set, for example, by connecting a selectable number of driver transistors (of the same size or of different sizes) in parallel in each of the two branches within the driver which are between the output-side data line and the “high” or “low” logic potential. However, this setting can also be individually made for each (or only one) of the two paths, as stated below.
Pull-up driver strength, that is to say the intensity of the driver current for the “high” level (for example binary value “1”) of the binary transmission signal. This parameter can be set, for example, by connecting a selectable number of driver transistors (of the same size or of different sizes) in parallel in that branch of the driver which is between the output-side data line and the “high” logic potential.
Pull-down driver strength, that is to say the intensity of the driver current for the “low” level (for example binary value “0”) of the binary transmission signal. This parameter can be set, for example, by connecting a selectable number of driver transistors (of the same size or of different sizes) in parallel in that branch of the driver which is between the output-side data line and the “low” logic potential.
Duty ratio of the data pulses; can be set, for example, using a variable delay circuit for the leading or trailing edge of the data pulses.
Slope of the leading edge of the data pulses; can be set, for example, using a variable RC element.
Slope of the trailing edge of the data pulses; can be set, for example, using a variable RC element.
Phase angle of the data pulses with respect to a common time reference (for example relative to strobe pulses which are transmitted in parallel with the data signals); can be set using a variable delay circuit.

For the purpose of setting such parameters, the value registers VR of a circuit arrangement of the type shown in FIGS. 1 to 3 are connected to corresponding trimming circuits of the transmission drivers ST in such a manner that the bits stored in the value registers control the setting of the respective trimming circuits. By way of example, the four value registers VR0:3 may thus be assigned to the trimming circuits for the phase angle of the data pulses from the four transmission amplifiers ST0:3, and the four value registers VR4:7 may be assigned to the trimming circuits for the driver current intensity of these four transmission amplifiers. This is illustrated in FIGS. 1 to 3 using appropriately labeled control lines at the transmission drivers. The respective trimming circuits are indicated using small rectangular boxes at the top and right-hand edges of the transmission driver symbols. In the example shown, each trimming circuit may be put into a selected one of 2⁴=16 different states in accordance with the 4-bit value information which is stored in the assigned value register VR.

In order to trim, for example, the phase angle of the data pulses transmitted by the transmission driver ST0, the destination information for the value register VR0 is input at the group GZ of address pins AP, and an item of value information for a delay time T_{R} that determines the delay of the transmitted data pulses is input at the group GV. This input is effected with the aid of the MRS command, as described further above in connection with FIGS. 1 to 3. Delay setting values for the other transmission drivers ST1:3 can then be input to the value registers VR1:3 in the same manner.

In a subsequent test operation, reading operation can be switched on in order to transmit a known test pattern (which is generated in the RAM module) of data to the controller (not shown) via the transmission drivers STO:3 and the data pins DP0:3. The read data received via the controller can be compared with the known pattern. Any possible errors can be analyzed in order to determine whether and in what sense the set parameter T_{R} needs to be changed. Repeating this sequence of setting and test steps with parameter values which are respectively changed finally makes it possible to find the optimum settings.

Another parameter, for example the current intensity of the transmission drivers ST0:3, may be “trained” in a similar manner to the above-described training of the phase angle, the destination information respectively selecting one of the value registers VR4:7 in the setting steps. The other parameters of the transmission driver parameters listed above can also be trained in a corresponding manner. Of course, a respective dedicated value register must be provided for each parameter of each transmission driver.

Training may be effected automatically under the control of a “training” program which may be installed in a separate test apparatus or in the controller. A subroutine may also be inserted, if desired, into such a program in order to individually trim parameters of the assigned data reception paths within the controller. This applies, in particular, to the phase of the received data pulses with respect to the strobe signal which is received at the controller together with the data, via a strobe line, during reading operation and forms the time reference there for sampling the received data bits.

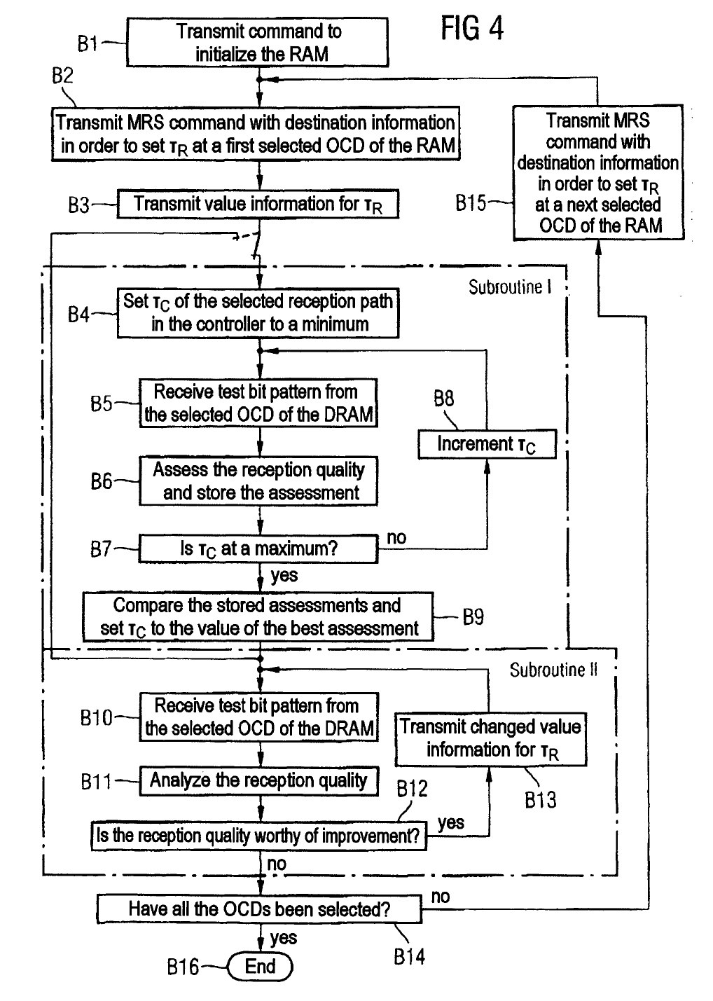

One example of a trimming or training program which implements the inventive method is described below with reference to the flowchart shown in FIG. 4, to be precise in its execution for trimming the data pulse phase at the data transmission amplifiers of the RAM module, the common abbreviation OCD (“Off-Chip Driver”) being used below to denote said data transmission amplifiers. The trimming or “training” program shown in FIG. 4 contains a multiplicity of steps which are shown in the form of blocks B1 to B16 and are explained in order below:
B1 The controller initializes the RAM module. This is usually effected by switching a CKE (“Clock Enable”) signal to a high level (H level). The controller applies said signal, via a separate line, to a CKE input of the RAM module (not shown in FIGS. 1 to 3). The RAM module is now receptive to the clock signal CLK at the clock input, and its command decoder 10 decodes commands which are received at the command inputs CPO:3.
B2 The controller transmits the MRS (“mode register set”) command and the destination information for the value register (for example VR0) to which the value—which is to be set at a selected first OCD (for example ST0)—for a delay time T_{R} is intended to be input, said delay time determining the phase angle of the data pulses transmitted by the OCD.
B3 The controller transmits an item of value information for T_{R}, preferably the value in the middle of the T_{R} setting range. This is used to set a delay device in the relevant OCD to this value. A subroutine I which comprises steps B4 to B9 and is intended to carry out the abovementioned controller trimming is then run:
B4 A delay time T_{C} which determines the strobe/data phase relationship in that data reception path of the controller which is assigned to the selected OCD of the RAM module is set to a minimum value in the controller. The relevant reception path is selected in the controller using the OCD identification contained in the destination information which is transmitted in step B2.
B5 The controller orders the RAM module to transmit a test bit pattern via the OCDs, said test bit pattern being “known” to the controller. This pattern can be generated by a separate pattern generator in the RAM module (however, it could also be transmitted, during reading operation, by reading particular memory cells in which this pattern was stored by the controller during previous writing operation). The test bit pattern from the output of the selected OCD is received in the controller via the selected data reception path.
B6 The controller tests the reception quality of the test bit pattern, for example by comparing it with the original (which is known to said controller), and stores an assessment of this quality for the T_{C} value that has been set.
B7 Branch: since T_{C} was not set to the maximum value in step B4, the program passes to step B8.
B8 The value of the delay T_{C} is incremented and the step sequence B5 to B7 is run through several times until T_{C} has been incremented to the maximum value. The branch then leads from step B7 to step B9.
B9 The assessments stored when running through the loop B7-B8-B5-B6 in subroutine I are compared. The delay T_{C} in the controller is definitively set to that value which resulted in the best assessment. Controller trimming for the selected data reception path is thus concluded, and the program passes to step B10 with which a subroutine 11 which comprises steps B10 to B13 begins in order to trim the delay T_{R} at the selected OCD in the RAM module.
B10 As in step B5, the test pattern is transmitted again, by the RAM module, via the selected OCD and is received in the controller via the assigned data reception path.
B11 The controller analyzes the reception quality of the test bit pattern, for example by comparing it with the original (which is known to said controller).
B12 Branch: if the reception quality should be improved, the program passes to step B13.
B13 The controller transmits a changed item of value information for T_{R} to the RAM module. This is used to set the delay device in the relevant OCD to another value, and subroutine II (loop of steps B10-B11-B12-B13) is run through with a respective new T_{R} setting until the reception quality analyzed in step B12 can no longer be improved. T_{R} trimming at the selected OCD is then concluded, and the program passes from branch B12 to branch B14.

B14 Branch: if all of the OCDs in the RAM module have not yet been selected for T_{R} trimming, the program passes to step B15.
B15 The controller transmits the MRS (“mode register set”) command and the destination information for that value register (for example VR1) which determines the delay value T_{R} that is to be set at a next selected OCD (for example ST1). Step B3 in which an item of value information for T_{R} is transmitted to the relevant value register then follows again. This is used to set a delay device in the relevant OCD to this value. Subroutines I and II (already described) for trimming the T_{C} of that controller reception path which is assigned to the currently selected OCD of the RAM module and for trimming the T_{R} at this OCD are then run again. As long as it is decided at branch B14 that all of the OCDs have not yet been selected for T_{R} trimming, the program passes each time from B14 to step B15 again in order to select a further OCD.
B16 End of the T_{R} trimming program if it is decided at branch B14 that T_{R} trimming has been carried out at all OCDs.

The same program may be used to trim any desired other parameters of the OCDs. The variable for the main program is the destination information for selecting the OCDs and the parameter which is to be trimmed. The variable for trimming subroutine II is the value information for prescribing the values of the respective parameter which are to be tried out. If a plurality of parameters are intended to be trimmed at each OCD, the entire program may be run several times in succession, with another parameter being defined each time in the destination information. However, subroutine I (steps B4-B5-B6-B7-B8-B9) for trimming the data/strobe phase relationship in the controller needs to be run through only during one run of the program, preferably when the latter is run for the first time. The subroutine is skipped during subsequent repetitions of the entire program for trimming other parameters of the OCDs. This is symbolized in FIG. 4 by the switch depicted after block B3 and the connected bridging program path to block B10. However, subroutine I may also be entirely omitted.

Subroutine II for trimming the parameters at the OCDs of the RAM module (loop B10-B11-B12-B13) may also be designed in such a manner that the value information (T_{R} in the example shown in FIG. 4) is changed incrementally from the minimum value to the maximum value of the value range, assessments of the reception quality being stored for all values and then the value which produced the best reception quality being used to definitively set the parameter, in a similar manner to that described in connection with subroutine I.

Another variant is to integrate subroutine II in subroutine I, for example by putting the loop B10-B11-B12-B13 in the place of the step sequence B5-B6.

It shall also be noted that the expression “controller” which is used in the description above and also in the patent claims is also representative of a graphics processor which assumes the role of the controller module (which is otherwise customary) during the operation of graphics memory modules.

While the foregoing is directed to embodiments of the present invention, other and further embodiments of the invention may be devised without departing from the basic scope thereof, and the scope thereof is determined by the claims that follow.

What is claimed is:

1. A random assess memory module, comprising:
a command input for receiving external operating commands;
additional terminals for inputting and outputting memory data and for inputting address information; a plurality of the additional terminals being dedicated control information terminals dedicated to inputting control information for various operating parameters; and wherein a first group of the control information terminals is dedicated to inputting destination information which indicates a respective parameter to be set, and wherein a second group of the control information terminals is dedicated to inputting value information for the respective parameter to be set
a register arrangement comprising a plurality of value registers and configured to be activated using a control signal in order to store the control information which has been input at the dedicated control information terminals; wherein the register arrangement contains, for each element in a set of M different operating parameters, a respective value register which is individually assigned, can be set by an individual control signal and is configured to store an item of value information that has been input for the respective parameter to be set; and
a selection device configured to be controlled using the destination information which has been input at the first group of control information terminals in order to transmit the value information which has been input at the second group of control information terminals only to that value register which is assigned to the indicated parameter.

2. The RAM module of claim 1, wherein the two groups of control information terminals are subsets of a set of control information terminals, wherein at least one of control information terminals of the set is included with both of the subsets;
and further comprising storage elements which, when a setting command applied to the command inputs is received, are configured to store the information which has been input at one of the two groups of control information terminals for the purpose of combining the information with information which is subsequently applied to the other of the two groups of control information terminals.

3. The RAM module of claim 2, wherein the storage elements are formed by a buffer memory which, in response to the setting command, stores the destination information input at the first group of control information terminals, and wherein the selection device comprises a 1-of-M decoder which responds to the stored destination information in order to select that copy of the M value registers which is indicated by the stored destination information for the purpose of holding the value information which is subsequently input at the second group of control information terminals.

4. The RAM module of claim 2, wherein the storage elements are formed by a buffer memory which, in response to the setting command, stores the value information which has been input at the second group of control information terminals, and wherein the selection device comprises a 1-of-M decoder which responds to the destination information which is subsequently input at the first group of control information terminals in order to select that copy of the M value registers which is indicated by the destination information in the first group of control information terminals for the purpose of holding the value information which is stored in the second group of control information terminals.

5. The RAM module of claimed in claim 1, wherein the two groups of control information terminals are subsets of a set of control information terminals.

6. The RAM module of claim 5, further comprising a first buffer memory which, in response to the setting command, stores the destination information which has been input at the first group of control information terminals;
a second buffer memory which, in response to the setting command, stores the value information which has been input at the second group of control information terminals; and
a 1-of-M decoder which responds to the destination information stored in the first buffer memory in order to select that copy of the M value registers indicated by the destination information for the purpose of holding the value information which is stored in the second buffer memory.

7. The RAM module of claim 6, wherein the buffer memories are each a respective preselected group of cells in a primary mode register.

8. The RAM module of claim 1, further comprising:
a plurality of transmission drivers for transmitting memory data to a memory controller; wherein each transmission driver is respectively individually assigned at least one of the value registers in order to set at least one operating parameter of the respective transmission driver.

9. A method for trimming at least one selected operating parameter of a RAM module, the method comprising:
receiving a mode setting command at a command input of the RAM module, the command input being for receiving external operating commands;
in response to the mode setting command, performing a setting step in which destination information which indicates a parameter to be trimmed and a value for the parameter to be trimmed are input at dedicated control information terminals of the RAM module in order to receive the value into a value register of the RAM module which is assigned to the parameter to be trimmed; wherein the dedicated control information terminals are selected from one or more address terminals and data terminals;
testing the operation of the memory module, the operation taking place with the received value of the parameter to be trimmed;
if the tested operation is not satisfactory, repeating the setting step and the testing step one or more times with the same destination information and a respectively changed value of the parameter to be trimmed for each instance the steps are repeated until a desired result of the testing step is achieved.

10. The method of claim 9, further comprising repeating the receiving, setting and testing in succession for different selected operating parameters of the RAM module.

11. The method of claim 10, wherein the selected operating parameters contains at least one operating parameter for each one of a plurality of transmission drivers configured to transmit memory data, which have been read out from the RAM module, to a memory controller.

12. The method of claim 11, wherein the dedicated control information terminals at which respective destination information and values for the operating parameters of the transmission drivers are input are only address terminals of the RAM module.

13. The method of claim 11, wherein the selected operating parameters for each transmission driver is selected from at least one of: an intensity of the driver current; a pull-up driver strength; a pull-down driver strength; a duty ratio of data pulses; a slope of a leading edge of the data pulses; a slope of a trailing edge of the data pulses; a phase angle of the data pulses with respect to a common time reference; and any combination thereof.

14. The method of claim 9, wherein, during the testing, a test data pattern is transmitted, via a transmission driver which is selected using the destination information, to an assigned data reception path of a controller connected to the RAM module, and a reception quality of the test data pattern is tested in the controller.

15. The method of claim 9, further comprising, after the setting step and before the testing, performing a controller trimming out of a memory controller communicatively connected to the RAM module, the controller trimming comprising:
i) transmitting a test data pattern, via a transmission driver which is selected using the destination information, to an assigned data reception path of the memory controller, wherein a reception quality of the test data pattern is tested in the memory controller; and
ii) a relative phase angle of the received test data with respect to a time reference is set in such a manner that the reception quality of the test data is optimal.

16. The method of claim 15, wherein
step i) of the controller trimming is repeated several times, a different delay time between the received test data and the time reference being set each time, and an assessment of the reception quality being stored; and wherein
in step ii) of the controller trimming, the delay time is set to that value which resulted in a best assessment of the reception quality.

17. The method of claim 9, wherein the value register is one of a plurality of value registers in a register arrangement configured to be activated using a control signal in order to store the control information which has been input at the dedicated control information terminals; wherein the register arrangement contains, for each element in a set of M different operating parameters, a respective value register which is individually assigned, can be set by an individual control signal and is configured to store a respective value that has been input for the respective parameter to be set.

18. The method of claim 17, wherein the RAM module further comprises a selection device configured to be controlled using the destination information which has been input at the control information terminals in order to transmit the value which has been input at the control information terminals only to that value register which is assigned to the parameter to be set indicated by the destination information.

19. A random assess memory module, comprising:
a command input for receiving external operating commands;
additional terminals comprising data terminals for inputting and outputting memory data and address terminals for inputting address information; a plurality of the additional terminals being dedicated control information terminals dedicated to inputting control information for various operating parameters each defined by a plurality of values; and wherein a first group of the control information terminals is dedicated to inputting destination information which indicates a respective parameter to be set, and wherein a second group of the control information terminals is dedicated to inputting values for the respective parameter to be set;
a register arrangement comprising a plurality of value registers and configured to be activated using a control signal in order to store the control information; wherein the register arrangement contains, for each value in a set of M different operating parameters, a respective value register configured to be set by an individual control signal and configured to store one of the values for the respective parameter to be set, the value to be stored being provided from the second group of the control information terminals; and
a selection device which, for a given destination information input at the first group of control information terminals, transmits the values which have been input at the second group of control information terminals, only to those respective value registers which are assigned to the parameter to be set indicated by the given destination information.

20. The RAM module of claim 19, wherein the two groups of control information terminals include at least one common terminal from the addition terminals.

21. The RAM module of claim 19, further comprising storage elements which, when a setting command applied to the command inputs is received, are configured to store the information which has been input at one of the two groups of control information terminals for the purpose of combining the information with information which is subsequently applied to the other of the two groups of control information terminals.

22. The RAM module of claim 19, further comprising
a first buffer memory which, in response to the setting command, stores the destination information input at the first group of control information terminals; and
a second buffer memory which, in response to the setting command, stores the values input at the second group of control information terminals; and wherein the selection device comprises a 1-of-M decoder which responds to the destination information stored in the first buffer memory in order to select that copy of the M value registers indicated by the destination information for the purpose of holding the values stored in the second buffer memory.
